(19) United States
(12) Patent Application Publication
(10) Pub. No.: US 2016/0260934 A1
(43) Pub. Date: Sep. 8, 2016

(54) CRUCIBLE FOR EVAPRATION OF SUBLIMATE OLED MATERIAL

(71) Applicant: SHENZHEN CHINA STAR OPTOELECTRONICS TECHNOLOGY CO., LTD., Shenzhen, Guangdong (CN)

(72) Inventor: Yawei LIU, Shenzhen, Guangdong (CN)

(73) Assignee: SHENZHEN CHINA STAR OPTOELECTRONICS TECHNOLOGY CO., LTD., Shenzhen, Guangdong (CN)

(21) Appl. No.: 14/422,687

(22) PCT Filed: Feb. 6, 2015
(86) PCT No.: PCT/CN2015/072348

§ 371 Date: Feb. 19, 2015

(30) Foreign Application Priority Data
Oct. 28, 2014 (CN) 201410593595.6

(51) Int. Cl. H01L 51/56; C23C 14/24; H01L 51/00

(52) U.S. Cl. CPC H01L 51/56; H01L 51/001; H01L 51/0021; C23C 14/243; H01L 51/5221

(57) ABSTRACT

The present invention provides a crucible for evaporation of a sublimate OLED material, which includes a body (1) and a top cover (2) connected to the body (1). The top cover (2) includes a gas outlet opening (21) formed in a top center thereof. The body (1) has an inside surface that is tapering in such a way that an inside diameter of an end of the body (1) that is close to the top cover (2) is greater than an inside diameter of an end of the body (1) that is distant from the top cover (2). The present invention provides a crucible inside wall that is arranged to include predetermined tapering so that after a portion of the OLED material sublimates, a remaining portion of the solid OLED material is acted upon by the gravity to get descending, maintaining sufficient contact with the crucible inside wall so as to be more sufficiently heated thereby ensuring stability of the evaporation speed.

### BACKGROUND OF THE INVENTION

1. Field of the Invention

The present invention relates to the field of OLED (Organic Light-Emitting Diode) manufacturing processes, and in particular to a crucible for evaporation of a sublimate OLED material.

2. The Related Arts

OLED is a flat panel displaying technique of extremely prosperous future and it shows excellent displaying performance and also possesses various advantages, such as being self-luminous, simple structure, being ultra-thin, fast response, wide view angle, low power consumption, and being capable of achieving flexible displaying and is thus regarded as a “dream display”. In addition, the investment of manufacturing installation is far less than that of TFT-LCDs (Thin-Film Transistor Liquid Crystal Displays) so that it is now favored by major display manufacturers and becomes the mainstream of the third-generation display devices in the field of displaying technology. Being on the eve of mass production, new techniques of OLED emerge virtually unlimitedly with the deepening of research and development thereof and thus, OLED displays are undergoing a break-through progress.

Two types of processes have been used in manufacturing OLED organic material films. For high-molecule OLED organic materials, a solution based film forming process is used; however, such a process is still in laboratory test stage. For small-molecule OLED organic materials, a vacuum thermal evaporation based film forming process is commonly used currently. Such a process is widely used by most manufacturers of the flat panel display industry, such as Samsung and LG. The vacuum thermal evaporation technique is to apply heating, in a vacuum environment of less than 5×10⁻⁵Pa, to change a material from a solid state to vapor state and gas molecules moving at a high speed reach a glass substrate and get deposited on the substrate to convert back into a solid state film of the OLED material. For a meltable material, when heated, it changes from the solid state to a liquid state and finally becomes gas molecules. Such a material requires no severe standards for the internal shape of a crucible for a liquid substance flows everywhere to get in sufficient contact with the internal wall of the crucible. However, for a sublimateable substance, when heated, it changes directly from a solid state into gas molecules. A conventional crucible for use in evaporation of an OLED material is illustrated in FIG. 1, which comprises a body 100, a top cover 200 connected to the body 100, and a gas outlet opening 210 formed in the center of the top cover 200. The body 100 that is used to receive and contain therein an OLED material 300 has an inside wall that is cylindrical. Since a solid substance lacks flowability, during the process of heating and sublimation of the material, the situation illustrated in FIG. 2 is very likely to happen, where after the OLED material is heated, a portion of the OLED material that is in contact with the inside wall of the crucible gets sublimating first, turning into gas molecules and getting away, with a portion of the solid OLED material left and not flowable so that the remaining OLED material cannot get into contact with the inside wall of the crucible, leading to instability of sublimation speed. If the facility is operated in a constant rate mode, then to maintain the sublimation speed, the facility has to continuously apply heating to increase the temperature. This may eventually exceeds the decomposition temperature of the OLED material and causes quality change of the OLED material.

### SUMMARY OF THE INVENTION

An object of the present invention is to provide a crucible for evaporation of a sublimate OLED material, which comprises a crucible inside wall arranged to show predetermined tapering so that when an OLED material sublimates, remaining solid OLED material is caused by the gravity to descend down, maintaining sufficient contact with the crucible inside wall to be more sufficiently heated thereby ensuring stability of evaporation speed.

To achieve the above object, the present invention provides a crucible for evaporation of a sublimate OLED material, which comprises a body and a top cover connected to the body. The top cover comprises a gas outlet opening formed in a top center thereof. The body has an inside surface that is tapering in such a way that an inside diameter of an end of the body that is close to the top cover is greater than an inside diameter of an end of the body that is distant from the top cover.

The inside surface of the body defines an included angle with respect to a vertical direction, which is between 0 to 65 degrees.

The inside surface of the body defines an included angle with respect to a vertical direction, which is preferably between 5 to 25 degrees.

The crucible is made of a material selected from stainless steel, titanium, or aluminum.

The inside wall the crucible has surface roughness that is between Ra.0 to Ra.15.

The top cover comprises a base portion and a gas outlet portion connected to the base portion. The gas outlet opening is formed in a center of the gas outlet portion. The base portion has an outside surface that shows a cylindrical configuration. The gas outlet portion has an outside surface that is in the form of a circular truncated cone. The body has an outside surface that is cylindrical.

The base portion has an outside diameter that is greater than an outside diameter of the body and the outside diameter of the body is greater than outside diameters of the gas outlet portion.

The outside diameter of the gas outlet portion at the end thereof close to the base portion is greater than the outside diameter of the gas outlet portion at the end thereof distant from the base portion.

The base portion has an inside diameter that is greater than the inside diameters of the body and the inside diameters of the body are greater than diameters of the gas outlet opening.

The diameter of the gas outlet opening at an end thereof close to the base portion is greater than the diameter of the gas outlet opening at an end thereof distant from the base portion.

The sublimate OLED material comprises an organic material that is used to form an OLED organic layer or an inorganic material for forming an OLED metal cathode and LiF.

The efficacy of the present invention is that the present invention provides a crucible for evaporation of a sublimate OLED material, which comprises a crucible inside wall that is arranged to include predetermined tapering so that after a portion of the OLED material sublimates, a remaining portion of the solid OLED material is acted upon by the gravity to get descending, maintaining sufficient contact with the crucible inside wall so as to be more sufficiently heated thereby ensuring stability of the evaporation speed.

For better understanding of the features and technical contents of the present invention, reference is had to a detailed description of the present invention given below, together with the attached drawings. The drawings, however, are provided for illustration and description only and are not intended to impose undue limitations to the scope of the present invention.

### BRIEF DESCRIPTION OF THE DRAWINGS

The technical solution, as well as other beneficial advantages, of the present invention will become apparent from the following detailed description of an embodiment of the present invention, with reference to the attached drawings.

In the drawings:

FIG. 1 is a schematic cross-sectional view showing a conventional crucible for evaporation of an OLED material;

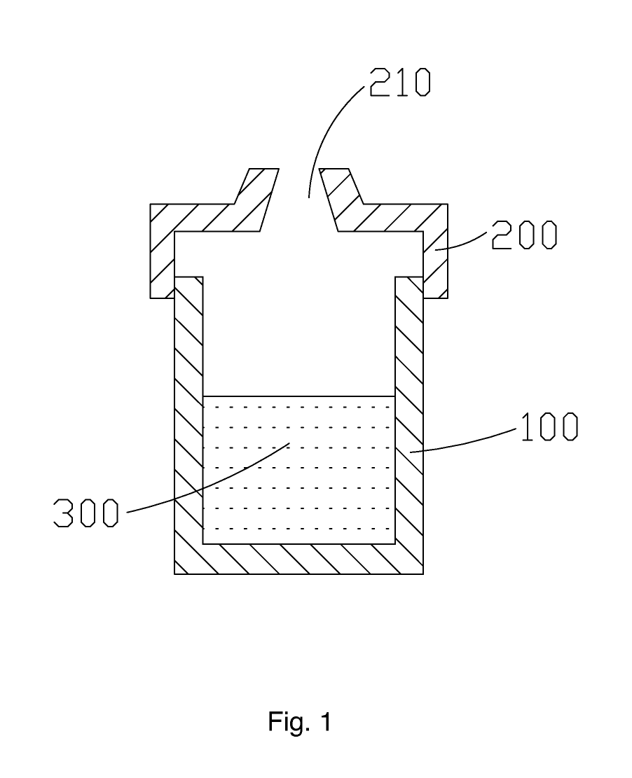

FIG. 2 is a schematic view illustrating a use of the crucible of FIG. 1 for evaporation;

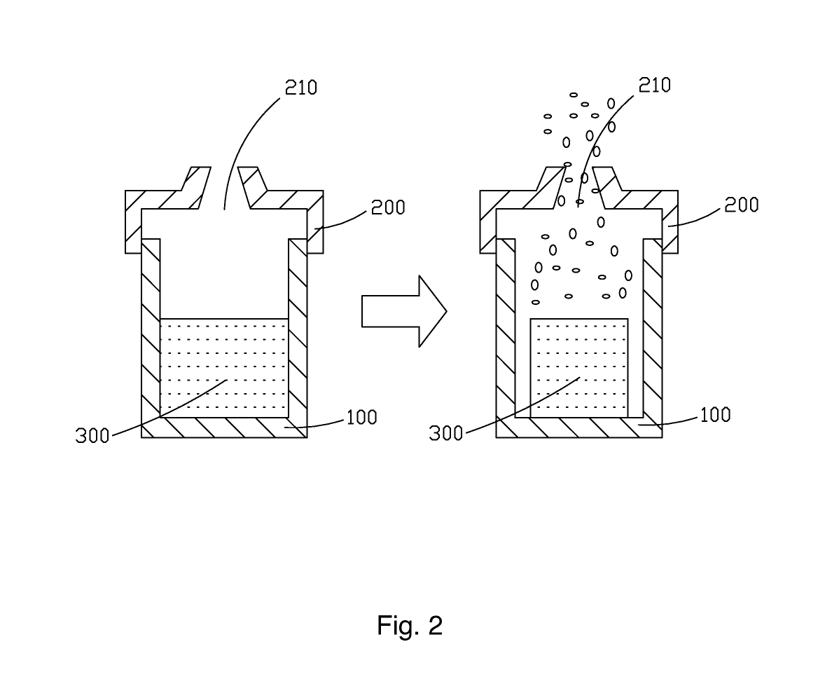

FIG. 3 is a schematic cross-sectional view showing a crucible for evaporation of a sublimate OLED material according to the present invention; and

FIG. 4 is a schematic view illustrating a use of the crucible of FIG. 3 for evaporation.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

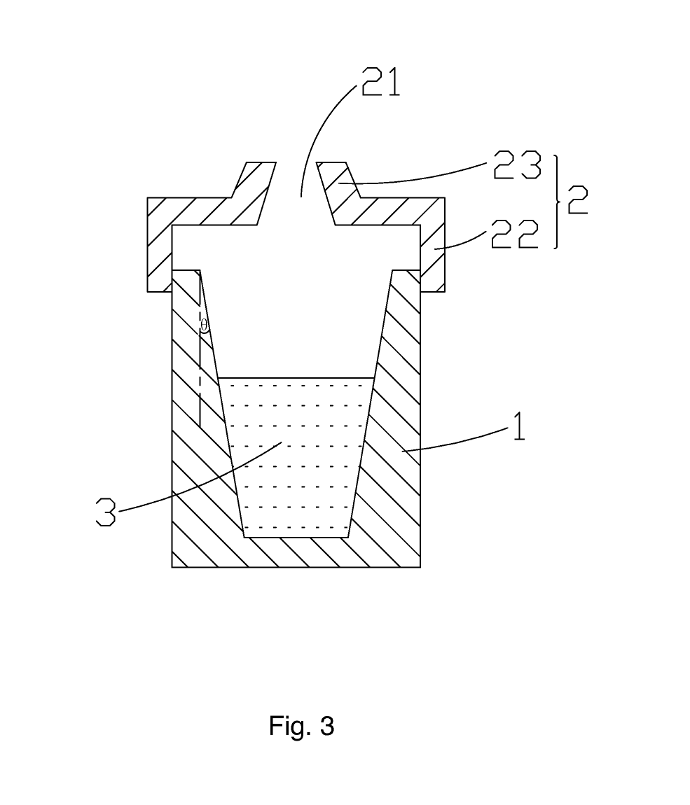

Referring to FIG. 3, the present invention provides a crucible for evaporation of a sublimate OLED material, which comprises a body 1 and a top cover 2 connected to the body 1. The top cover 2 comprises a gas outlet opening 21 formed in a top center thereof. The body 1 has an inside surface that is tapering in such a way that an inside diameter of an end of the body 1 that is close to the top cover 2 is greater than an inside diameter of an end of the body 1 that is distant from the top cover 2. The present invention is arranged, for a solid sublimate OLED material, to make the inside wall of the crucible in a form having predetermined tapering in order to ensure, after a portion of the OLED material sublimates, a remaining portion of the solid OLED material may descend down due to the action of the gravity to maintain sufficient contact with the inside wall of the crucible.

As shown in FIG. 3, the inside surface of the body 1 defines an include angle θ with respect to the vertical direction that is controlled to be between 0 to 65 degrees. Preferably, the included angle is between 5 to 25 degrees.

The crucible may be made of a material of stainless steel, titanium, aluminum or other metal materials.

The inside wall of the crucible has surface roughness that is Ra.0 to Ra.15 in order to increase the contact area between the inside surface and the material so that the OLED material 3 may be uniformly heated to ensure stability of the evaporation speed.

Further, as shown in FIG. 3, the top cover 2 comprises a base portion 22 and a gas outlet portion 23 connected to the base portion 22. The gas outlet opening 21 is formed in a center of the gas outlet portion 23. The base portion 22 has an outside surface that shows a cylindrical configuration. The gas outlet portion 23 has an outside surface that is in the form of a circular truncated cone. The body 1 has an outside surface that is cylindrical.

The base portion 22 has an inside surface having a lower rim that is connected to an upper rim of the outside surface of the body 1. The base portion 22 has an outside diameter that is greater than an outside diameter of the body 1. The outside diameter of the body 1 is greater than outside diameters of the gas outlet portion 23. The outside diameter of the gas outlet portion 23 at the end thereof close to the base portion 22 is greater than the outside diameter of the gas outlet portion 23 at the end thereof distant from the base portion 22. The base portion 22 has an inside diameter that is greater than the inside diameters of the body 1. The inside diameters of the body 1 are greater than diameters of the gas outlet opening 21. The diameter of the gas outlet opening 21 at an end thereof close to the base portion 22 is greater than the diameter of the gas outlet opening 21 at an end thereof distant from the base portion 22.

The sublimate OLED material can be an organic material that is used to form an OLED organic layer or an inorganic material for forming an OLED metal cathode and LiF.

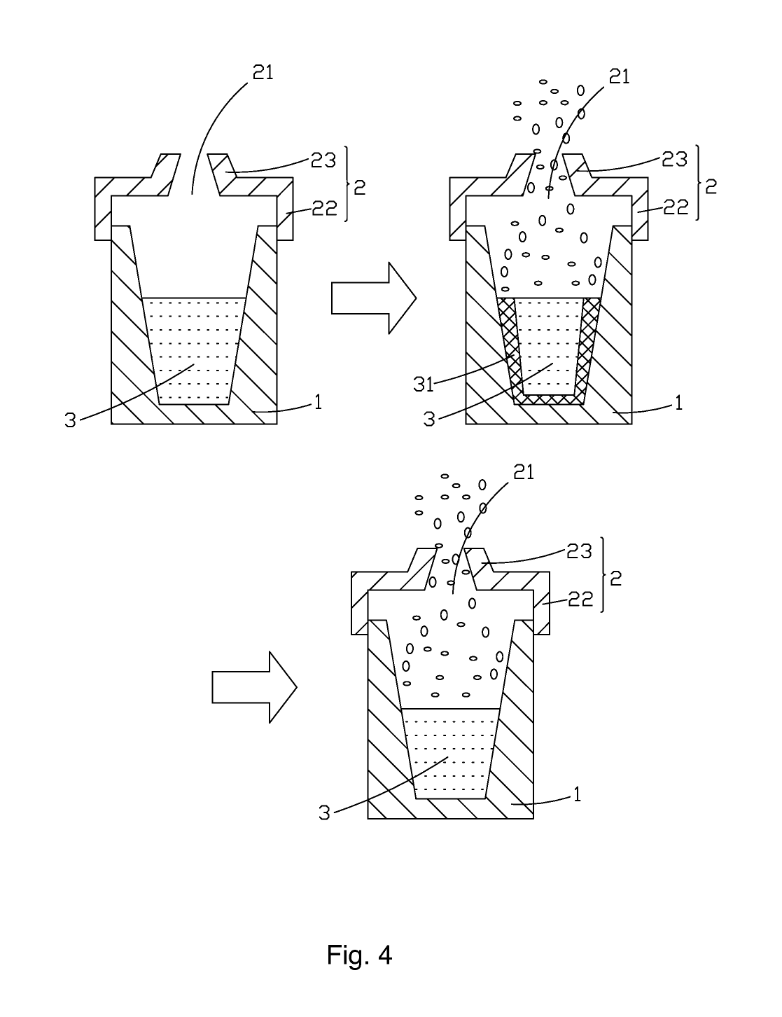

Referring to FIG. 4, when the crucible for evaporation of a sublimate OLED material according to the present invention is used to carry out an evaporation process, after the OLED material 3 contained in the body 1 is subjected to heating, the portion of the OLED material 31 at a location in contact with the inside surface of the crucible is first heated and gets sublimating and then evaporates and releases from the gas outlet opening 21. Due to the arrangement of the inclination angle θ of the crucible inside wall, the remaining portion of the OLED material is acted upon by the gravity to get descending, maintaining sufficient contact with the crucible inside wall so as to be more sufficiently heated thereby ensuring stability of the evaporation speed.

It is noted that the crucible is applicable to vacuum thermal deposition of OLED materials, including organic materials and inorganic materials including metal cathode and LiF, and is also applicable to other vacuum thermal deposition fields.

In summary, the present invention provides a crucible for evaporation of a sublimate OLED material, which comprises a crucible inside wall that is arranged to include predetermined tapering so that after a portion of the OLED material sublimates, a remaining portion of the solid OLED material is acted upon by the gravity to get descending, maintaining sufficient contact with the crucible inside wall so as to be more sufficiently heated thereby ensuring stability of the evaporation speed.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A crucible for evaporation of a sublimate OLED material, comprising a body and a top cover connected to the body, the top cover comprising a gas outlet opening formed in a top center thereof, the body having an inside surface that is tapering in such a way that an inside diameter of an end of the body that is close to the top cover is greater than an inside diameter of an end of the body that is distant from the top cover.

2. The crucible for evaporation of a sublimate OLED material as claimed in claim 1, wherein the inside surface of the body defines an included angle with respect to a vertical direction, which is between 0 to 65 degrees.

3. The crucible for evaporation of a sublimate OLED material as claimed in claim 1, wherein the inside surface of the body defines an included angle with respect to a vertical direction, which is preferably between 5 to 25 degrees.

4. The crucible for evaporation of a sublimate OLED material as claimed in claim 1, wherein the crucible is made of a material selected from stainless steel, titanium, or aluminum.

5. The crucible for evaporation of a sublimate OLED material as claimed in claim 1, wherein the inside wall the crucible has surface roughness that is between Ra.0 to Ra.15.

6. The crucible for evaporation of a sublimate OLED material as claimed in claim 1, wherein the top cover comprises a base portion and a gas outlet portion connected to the base portion, the gas outlet opening being formed in a center of the gas outlet portion, the base portion having an outside surface that shows a cylindrical configuration, the gas outlet portion having an outside surface that is in the form of a circular truncated cone, the body having an outside surface that is cylindrical.

7. The crucible for evaporation of a sublimate OLED material as claimed in claim 6, wherein the base portion has an outside diameter that is greater than an outside diameter of the body and the outside diameter of the body is greater than outside diameters of the gas outlet portion.

8. The crucible for evaporation of a sublimate OLED material as claimed in claim 7, wherein the outside diameter of the gas outlet portion at the end thereof close to the base portion is greater than the outside diameter of the gas outlet portion at the end thereof distant from the base portion.

9. The crucible for evaporation of a sublimate OLED material as claimed in claim 8, wherein the base portion has an inside diameter that is greater than the inside diameters of the body and the inside diameters of the body are greater than diameters of the gas outlet opening.

10. The crucible for evaporation of a sublimate OLED material as claimed in claim 9, wherein the diameter of the gas outlet opening at an end thereof close to the base portion is greater than the diameter of the gas outlet opening at an end thereof distant from the base portion.

11. The crucible for evaporation of a sublimate OLED material as claimed in claim 1, wherein the sublimate OLED material comprises an organic material that is used to form an OLED organic layer or an inorganic material for forming an OLED metal cathode and LiF.

12. A crucible for evaporation of a sublimate OLED material, comprising a body and a top cover connected to the body, the top cover comprising a gas outlet opening formed in a top center thereof, the body having an inside surface that is tapering in such a way that an inside diameter of an end of the body that is close to the top cover is greater than an inside diameter of an end of the body that is distant from the top cover;
wherein the inside surface of the body defines an included angle with respect to a vertical direction, which is between 0 to 65 degrees;
wherein the inside surface of the body defines an included angle with respect to a vertical direction, which is preferably between 5 to 25 degrees;
wherein the crucible is made of a material selected from stainless steel, titanium, or aluminum;
wherein the inside wall the crucible has surface roughness that is between Ra.0 to Ra.15;
wherein the top cover comprises a base portion and a gas outlet portion connected to the base portion, the gas outlet opening being formed in a center of the gas outlet portion, the base portion having an outside surface that shows a cylindrical configuration, the gas outlet portion having an outside surface that is in the form of a circular truncated cone, the body having an outside surface that is cylindrical;
wherein the base portion has an outside diameter that is greater than an outside diameter of the body and the outside diameter of the body is greater than outside diameters of the gas outlet portion;
wherein the outside diameter of the gas outlet portion at the end thereof close to the base portion is greater than the outside diameter of the gas outlet portion at the end thereof distant from the base portion;
wherein the base portion has an inside diameter that is greater than the inside diameters of the body and the inside diameters of the body are greater than diameters of the gas outlet opening;
wherein the diameter of the gas outlet opening at an end thereof close to the base portion is greater than the diameter of the gas outlet opening at an end thereof distant from the base portion; and
wherein the sublimate OLED material comprises an organic material that is used to form an OLED organic layer or an inorganic material for forming an OLED metal cathode and LiF.
